(19) United States
(12) Patent Application Publication
(10) Pub. No.: US 2002/0175358 A1
(43) Pub. Date: Nov. 28, 2002

(54) Semiconductor memory device and method of manufacturing the same

(75) Inventor: Shintaro Yamamichi, Tokyo (JP)

Correspondence Address: Scully, Scott, Murphy & Presser, 400 Garden City Plaza, Garden City, NY, 11530, US

(73) Assignee: NEC Corporation, Tokyo (JP)

(21) Appl. No.: 10/189,078

(22) Filed: Jul. 3, 2002

Related U.S. Application Data
(62) Division of application No. 09/368,926, filed on Aug. 5, 1999.

(30) Foreign Application Priority Data
Sep. 1, 1998 (JP) 10-247589

(51) Int. Cl. H01L 27/108; H01L 29/76; H01L 29/94; H01L 31/119

(52) U.S. Cl. 257/296

(57) ABSTRACT

A semiconductor memory device is provided which is capable of suppressing an increase in leakage current of thin film capacitors formed by use of high dielectric constant film and controlling the threshold voltage of transistors at a desired value.

The semiconductor memory device is formed by integrating transistors and thin film capacitors, a part or the whole of which are formed by high dielectric constant or ferroelectric films, on a semiconductor substrate. The semiconductor memory device is characterized in that it contains deuterium at a ratio higher than the natural abundance ratio of deuterium to hydrogen at an interface between the semiconductor substrate and a gate insulating film.

### BACKGROUND OF THE INVENTION

1. Field of the Invention

This invention relates to a semiconductor memory device which is formed by integrating transistors and thin film capacitors on a semiconductor substrate and a method of manufacturing the same.

2. Background Art

Conventionally, thin film capacitors in semiconductor integrated circuits such as Dynamic Random Access Memories (DRAM) have been mainly constructed by a laminated structure by alternately stacking silicon oxide films and silicon nitride films, and by a pair of polysilicon electrodes formed on both upper and lower surfaces of the laminated structure. Recently, however, as the size of the memory cell has diminished, in order to attain the capacitor density required for increasing capacities in DRAMs of more than 1 Gb for the reduced size memory cell, the formation of extremely thin SiO₂ equivalent thickness smaller than 1 nm has become necessary.

A method to provide a required high capacitor density is disclosed in, for example, “1994 International Electron Devices Meeting Technical Digests, pp. 831 to 834”, in which, SrTiO₃ having a high dielectric constant of about 300 at room temperature or dielectric films such as (Ba,Sr)TiO₃ having higher dielectric constant than. SrTiO₃ are used as capacitor insulating films, and a barrier metal layer such as Pt/Ta or RuO₂/TiN is used as the lower electrode, since this barrier metal layer does not form a low dielectric oxide layer in an oxidizing atmosphere during deposition of a high dielectric constant film and also suppresses the diffusion of silicon. There are many reports which show that it is possible to produce memory devices capable of conducting non-volatile operations (Ferroelectric RAM) by use of ferroelectric films such as Pb(Zr, Ti)O₃ having high large remnant polarization at room temperature, being substituted for (Ba, Sr)TiO₃.

On the other hand, in the conventional manufacturing process, dangling bonds of silicon atoms at an interface of a gate oxide film and a silicon substrate are terminated by hydrogen atoms by annealing in a hydrogen atmosphere at the end of a wiring process. Thereby, it becomes possible to control the threshold voltage of a transistor at a desired value and to reduce a sub-threshold leakage current. Japanese Patent Application, First Publication No. Hei 8-507175 discloses that it is possible to control the threshold voltage better by use of deutrium atoms being substituted for hydrogen atoms.

However, a problem arises in that high dielectric constant films represented by (Ba,Sr)TiO₃ and ferroelectric films represented by the Pb(Zr,Ti)O₃ will incur an increase of the leakage current and disappearance of the ferroelectricity, respectively, due to separation of oxygen atoms in the film causing a degradation of the crystallinity after hydrogen annealing.

As described, for example, in the “1996 International Electron Devices Meeting Technical Digest” pp. 679 to 682 by Tung-Sheng Chen et al., the leakage current of the BST (Barium Strontium Titanate) capacitor at +1 V increases more than two orders when the BST capacitor is annealed in a hydrogen atmosphere at 400° C. for 30 min. The same article describes that the recovery annealing in nitrogen atmosphere at 550° C. for one hour is not satisfactory for the recover of the properties of the capacitor before the hydrogen annealing.

As hereinabove described, a problem has been encountered in that thermal annealing in a hydrogen atmosphere for the purpose of controlling the threshold voltage of the transistor in conventional semiconductor memory devices causes an increase in the leakage current in the high dielectric constant or ferroelectric films, which results in causing malfunction of the semiconductor memory devices due to decrease in electric charges stored in the memory cells as time passes.

The present invention is provided in order to solve the above problems.

### SUMMARY OF THE INVENTION

It is therefore an object of the invention to provide a semiconductor memory device comprising transistors and thin film capacitors that use high dielectric constant film or ferroelectric film partially or wholly, wherein the semiconductor memory device is capable of suppressing an increase in the leakage current of a thin film capacitor or maintaining good ferroelectric properties of a thin film capacitor, while maintaining the threshold voltage at a desired value; and to provide a method of manufacturing the semiconductor memory device.

In order to achieve the above mentioned objective, the following structures are adopted.

A semiconductor memory device according to the first aspect of the present invention comprises transistors and capacitor insulating films constituted of a high dielectric constant film or a ferroelectric film partially or wholly integrated on a semiconductor substrate, wherein the semiconductor memory device contains deuterium atoms at a ratio higher than the natural abundance ratio of deuterium to hydrogen atoms at the interface between a transistor and a gate insulating film and does not contain hydrogen atoms.

A semiconductor memory device according to the second aspect of the present invention comprises transistors and capacitor insulating films constituted by a high dielectric constant film or a ferroelectric film partially or wholly integrated on a semiconductor substrate, wherein the semiconductor memory device contains deuterium and does not contain hydrogen at the interface between the semiconductor substrate and a gate insulating film of the transistor.

According to the third aspect of the present invention, in a semiconductor memory device according to the first aspect or the second aspect, a part or the whole of the capacitor insulating film of the thin film capacitor is expressed, on the one hand, by a formula ABO₃, wherein A is at least one element selected from the group consisting of Ba, Sr, Pb, Ca, La, Li, and K; and B is at least one element selected from the group consisting of Zr, Ti, Ta, Nb, Mg, Mn, Fe, Zn, and W; and, on the other hand, the thin film capacitor is expressed by a formula (Bi₂O₃)(Aₘ₋₁Bₘ(O₃)ₘ₊₁ (m=1, 2, 3, 3, 4, 5), wherein A is at least one element selected from the group consisting of Ba, Sr, Pb, Ca, K, Bi; and B is at least one element selected from the group consisting of Nb, Ta, Ti, and W; or Ta₂O₅.

According to the fourth aspect of the present invention, the present invention provides a method of manufacturing a semiconductor memory device comprising the steps of: forming transistors at a designated locations on a semiconductor substrate; forming thin film capacitors by partial or whole use of high dielectric constant films or ferroelectric films; electrically separating the transistors and the thin film capacitors; and electrically connecting the transistors and the thin film capacitors; wherein the method of manufacturing the semiconductor memory devices further comprises a step of performing annealing in an atmosphere containing deuterium at a higher ratio than the natural abundance ratio of deuterium to hydrogen.

According to the fifth aspect of the present invention, a method of manufacturing semiconductor memory devices comprises the steps of: forming transistors at designated locations on a semiconductor substrate; forming thin film capacitors by partial or whole use of high dielectric constant films or ferroelectric films; electrically separating the transistors and the thin film capacitors; and electrically connecting the transistors and the thin film capacitors; wherein the method further comprises the steps of annealing the semiconductor memory devices in an atmosphere containing deuterium but not containing hydrogen.

According to the sixth aspect of the present invention, a method of manufacturing semiconductor memory devices comprises the steps of: forming transistors at a designated locations on a semiconductor substrate; forming thin film capacitors by partial or whole use of high dielectric constant films or ferroelectric films; electrically separating the transistors and the thin film capacitors; and electrically connecting the transistors and the thin film capacitors; wherein the method further comprises the steps of annealing the semiconductor memory devices in an atmosphere containing deuterium at a ratio higher than the natural abundance ratio of deuterium to hydrogen; and executing subsequent annealing thereof in an oxygen atmosphere.

According to the seventh aspect of the present invention, a method of manufacturing semiconductor memory devices comprises the steps of: forming transistors at designated locations on a semiconductor substrate; forming thin film capacitors by partial or whole use of high dielectric constant films or ferroelectric films; electrically separating the transistors and the thin film capacitors; and electrically connecting the transistors and the thin film capacitors; wherein the method further comprises the steps of annealing the semiconductor memory devices in an atmosphere containing deuterium but not containing hydrogen; and executing subsequent annealing thereof in an oxygen atmosphere.

According to the eighth aspect of the present invention, the method of manufacturing semiconductor memory devices comprises the steps of: forming transistors at a designated locations on a semiconductor substrate; forming thin film capacitors by partial or whole use of high dielectric constant films or ferroelectric films; electrically separating the transistors and the thin film capacitors; and electrically connecting the transistors and the thin film capacitors; wherein the method further comprising the steps of annealing the semiconductor memory devices in an atmosphere containing deuterium at a ratio higher than the natural abundance ratio of deuterium; and executing subsequent annealing thereof in an atmosphere containing nitrogen or an inert gas or a mixture of these gases.

According to the ninth aspect of the present invention, a method of manufacturing semiconductor memory devices comprises the steps of: forming transistors at designated locations on a semiconductor substrate; forming thin film capacitors by partial or whole use of high dielectric constant films or ferroelectric films; electrically separating the transistors and the thin film capacitors; and electrically connecting the transistors and the thin film capacitors; wherein the method further comprises the steps of annealing the semiconductor memory devices in an atmosphere containing deuterium but not containing hydrogen; and executing subsequent annealing thereof in an atmosphere containing nitrogen or an inert gas or a mixture of these gases.

### BRIEF DESCRIPTION OF THE DRAWINGS

FIG. 1 is a cross-sectional view of a semiconductor memory device for explaining the first embodiment of the present invention.

FIG. 2 shows the results of a comparison of the leakage current properties of the conventional semiconductor memory device and the first embodiment of the present invention.

FIG. 3 is a cross-sectional view of a semiconductor memory device for explaining the second embodiment of the present invention.

FIG. 4 shows the results of a comparison of the leakage current properties of the conventional semiconductor memory device and the first embodiment of the present invention.

FIG. 5 is a diagram showing a method of manufacturing the semiconductor memory device for explaining the third embodiment of the present invention.

FIG. 6 is a diagram showing a method of manufacturing a semiconductor memory device for explaining the fourth embodiment of the present invention.

### DETAILED DESCRIPTION OF THE INVENTION

Hereinafter, the present invention will be described in detail with reference to the attached drawings.

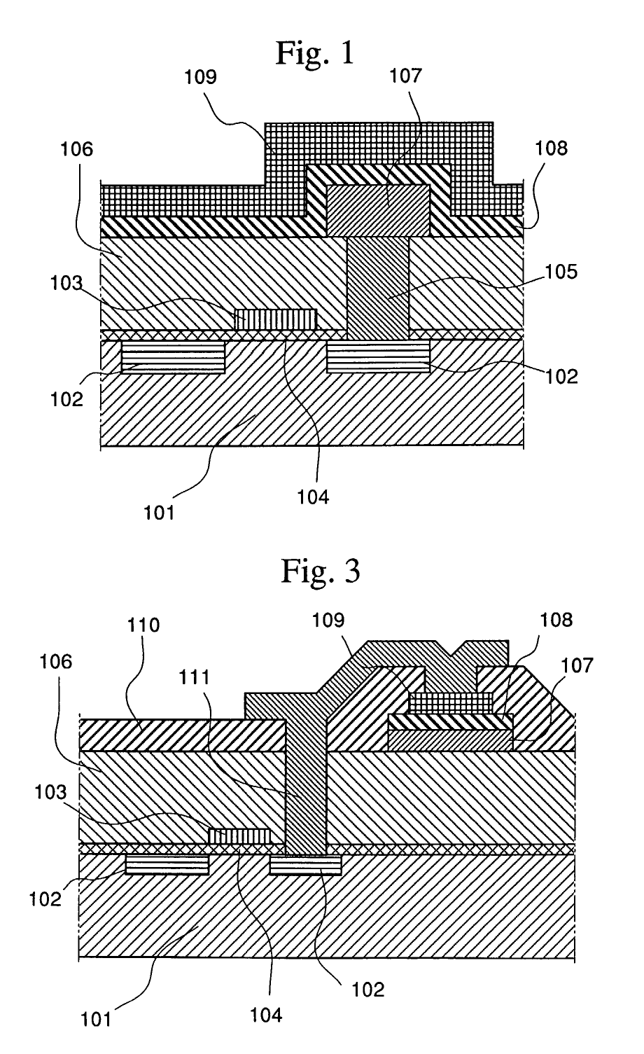

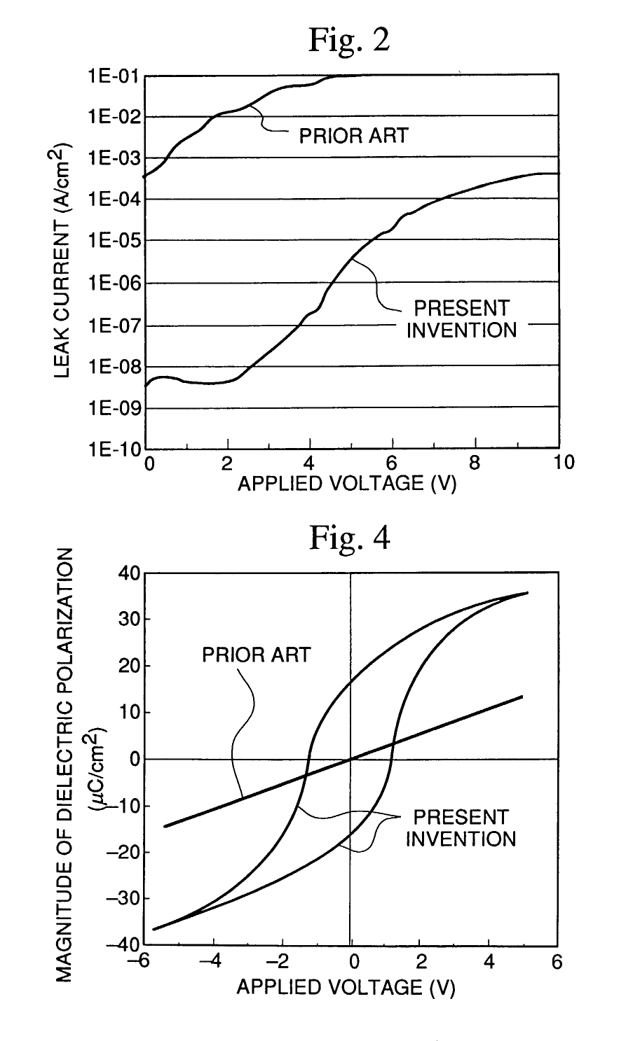

FIG. 1 is a cross-sectional view of a semiconductor memory device for explaining the first embodiment of the present invention. The reference numeral 101 denotes a silicon substrate, 102 denotes a source and a drain portions of a transistor made of silicon doped with arsenic, 103 a gate portion of the transistor made of arsenic doped polysilicon, 104 a gate insulating film of the transistor made of SiO₂, 105 a capacitor contact portion made of phosphorus doped polysilicon, 106 an interlayer film made mainly of SiO₂, 107 a lower electrode formed by a Ru/TiN/TiSiₓ film, 108 a capacitor insulating film made of high dielectric constant film made of (Ba,Sr)TiO₃, and 109 an upper electrode film made of Ru.

In the conventional semiconductor memory devices, dangling bonds of silicon atoms present at the interface between a gate insulating film 104 and a silicon substrate 101 are bound with hydrogen atoms and the deuterium atoms exist at a natural abundance ratio of 0.015%. In such a conventional structure, although the threshold voltage of a transistor can be maintained at a designated value, the leakage current of the high dielectric constant film made of (Ba,Sr)TiO₃ becomes too large to operate the semiconductor memory device.

In contrast, in a semiconductor memory device of the present invention, dangling bonds of silicon atoms present at the interface between the gate insulating film 104 and the silicon substrate 101 are bound with deuterium atoms, which results in preventing an increase in the leakage current in the high dielectric constant film made of (Ba,Sr)TiO₃, and the present device exhibits an excellent performance as a semiconductor memory device having a sufficient charge maintaining characteristic. In addition, the desired value of the threshold voltage of the transistor is obtained in the present structure.

FIG. 3 is a cross-sectional view of a semiconductor memory device for explaining the second embodiment of the present invention. Referring to the figure, on the silicon substrate 101, the source and the drain 102 of a transistor, the gate of the transistor 103 made of arsenic doped polysilicon, the gate insulating film 104 made of SiO₂ film, the interlayer insulating film 106 made mainly of SiO₂, the lower electrode film 107 made of Ir/IrO₂, a capacitor insulating film 108 made of high dielectric Pb(Zr, Ti)O₃, the upper electrode film 109 made of Ir/IrO₂, the second interlayer insulating film 110 made mainly of SiO₂, and a local wiring portion 110 made mainly of Al/TiN/Ti film are formed in sequence to form a semiconductor memory device.

In the conventional device, the dangling bonds of silicon atoms present between the gate insulating film 104 and the silicon substrate 101 are mainly bound with the hydrogen and the deuterium atoms exist at a natural abundance ratio of 0.015%. In such a conventional structure, although the threshold voltage can be controlled at a desired value, the hysteresis characteristic of the Pb(Zr,Ti)O₃ disappears as shown in FIG. 4, and it is impossible to use the semiconductor memory device to conduct a non-volatile operation.

In contrast, in the semiconductor memory device of the present invention, since the dangling bonds of silicon atoms at the interface between the gate insulating layer 104 and the silicon substrate 101 are bound with deuterium atoms, and since the satisfactory hysteresis characteristic of the ferroelectric Pb(Zr,Ti)O₃ film appears as shown in FIG. 4, the present device acts as the semiconductor memory device which is capable of maintaining sufficient charges even after the power source is stopped. The desired threshold voltage of the transistor is also obtained.

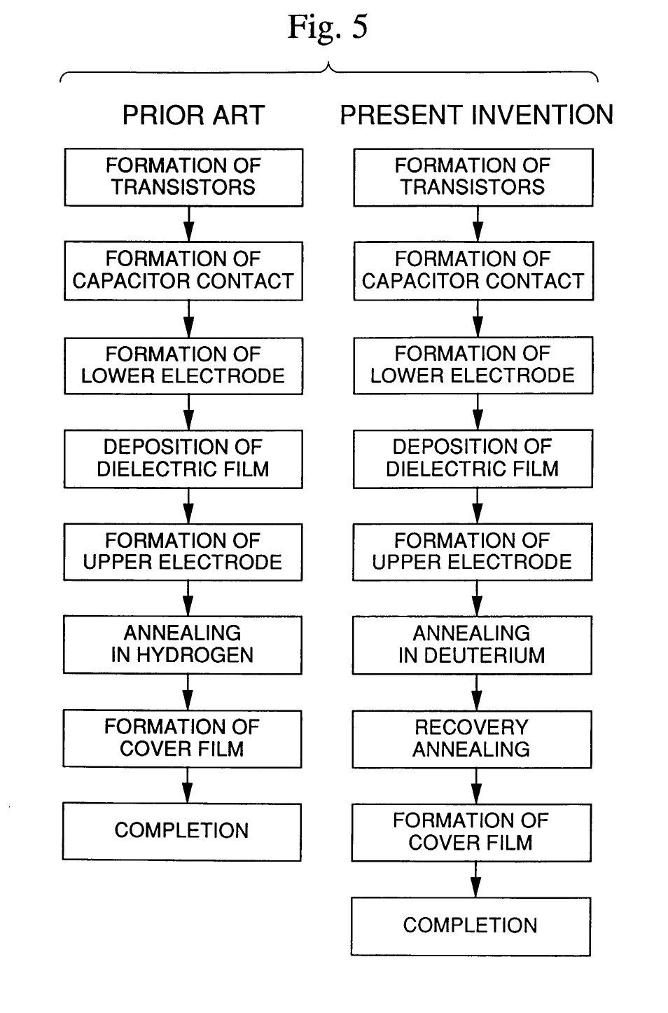

FIG. 5 is a diagram showing a sequence of the manufacturing processes of the semiconductor memory device for explaining the third embodiment of the present invention. In the conventional manufacturing process, in order to control the threshold voltage of a transistor at a desired value, the annealing in a hydrogen atmosphere is carried out immediately before the process of forming the cover film. Although the annealing in hydrogen assures a normal operation of the transistor, the leakage current in the high electric film increases due to the degradation of the crystallinity of the high dielectric constant film caused by the reduction by hydrogen.

In contrast, the manufacturing process of the present semiconductor memory device includes an annealing in the deuterium atmosphere being substituted for the conventional annealing in hydrogen, and the process further includes a recovery annealing process, for example, in oxygen at 600° C. for 1 hour after the annealing in deuterium before the cover film formation. Since the bonding energy of the deuterium atom to the silicon is higher than that of the hydrogen atoms, the deuterium atom is not isolated by the recovery annealing after the annealing in deuterium. Consequently, by use of the present manufacturing process, the leakage characteristic of the high dielectric constant film can be recovered to that before the deuterium annealing, while dangling bonds of silicon atoms between the gate insulating film and the silicon substrate are terminated by deuterium atoms.

In the conventional technique, the leakage characteristic of the high dielectric constant film is not perfectly recovered by the recovery annealing, and the recovery annealing often isolates hydrogen atoms bonded with the dangling bonds of silicon atoms, which results in shifting the threshold voltage from the desired value. By adopting the manufacturing process of the present invention, it becomes possible to manufacture a semiconductor memory device in which thin film capacitors using a high dielectric constant film with a superior leakage characteristic and transistors having the desired threshold voltage are integrated on the same substrate.

In addition, the recovery annealing can be carried out in atmospheres of nitrogen, or an inert gas, or their mixtures. By the recovery annealing, for example, in a nitrogen atmosphere at 600° C. for one hour, it is possible to terminate point defects of the dielectric films, while suppressing the oxidization of metal wiring of the semiconductor memory device, which results in improving the leakage characteristic of the semiconductor memory device.

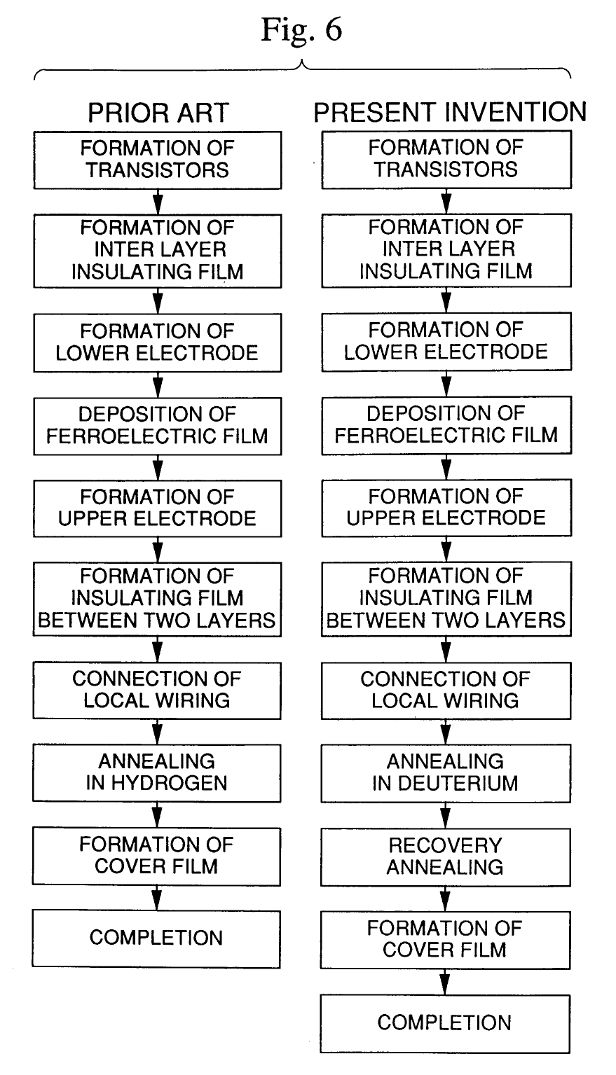

FIG. 6 is a flow chart showing the representative manufacturing process of the semiconductor memory device for explaining the fourth embodiment of the present invention. Conventionally, an annealing in hydrogen is carried out just before the cover film formation process. Although the normal operation of the transistor can be secured, the hysteresis characteristic of the ferroelectric film disappears due to the reduction by hydrogen.

In contrast, in the manufacturing process of the present invention, an annealing process in deuterium is adopted in place of the conventional annealing in hydrogen, and furthermore, an annealing process, for example, in oxygen at 600° C. for one hour is added to the conventional processes before the cover film formation process. Since the binding energy of the deuterium atom with dangling bonds of silicon atoms is greater than that of the hydrogen with dangling bonds of silicon atoms, the deuterium is not isolated from the silicon atom by the recovery annealing. Accordingly, the recovery annealing of the present invention makes it possible to restore the hysteresis characteristic of the ferroelectric film to the state before the deuterium annealing, while the dangling bonds of silicon atoms between the gate insulate film of the transistor and the silicon substrate are maintained as terminated by the deuterium.

In the conventional semiconductor memory device, the recovery annealing is not able to restore the hysteresis characteristic of the ferroelectric film perfectly to the original state and hydrogen atoms coupled with the dangling bonds of silicon atoms are made free, which shifts the threshold voltage of the transistors in the semiconductor memory device from a desired value.

The manufacturing process of the present invention makes it possible to provide a semiconductor memory device, in which thin film capacitors made of ferroelectric film having a superior hysteresis characteristic and transistors having a desired threshold voltage are integrated on the same substrate.

The recovery annealing can be carried out in nitrogen or in an inert gas. For example, the recovery annealing in nitrogen at 600° C. for one hour gives the same effect as that in an oxygen atmosphere, because the annealing in nitrogen terminates point defects of the dielectric films, while suppressing oxidization of the metal wiring in the semiconductor memory device.

In the descriptions concerning the first to the fourth embodiments of the present invention, (Ba,Sr)TiO₃ is given as an example of the high dielectric constant film and Pb(Zr,Ti)O₃ is given as an example of the ferroelectric film. However, examples of high dielectric constant and ferroelectric materials include compounds expressed by a formula ABO₃, in which A is more than one element selected from a group consisting of Ba, Sr, Pb, Ca, La, Li, K; and B is more than one element selected from the group consisting of Zr, Ti, Ta, Nb, Mg, Mn, Fe, Zn, and W; and examples of compounds expressed by ABO₃ include SrTiO₃, PbTiO₃, (Pb,La)(Zr,Ti)O₃, Pb(Mg,Nb)O₃, Pb(Mg,W)O₃, Pb (Zn,Nb)O₃, LiTaO₃, LiNbO₃, KTaO₃, and KNbO₃.

Furthermore, examples of high dielectric constant and ferroelectric materials include compounds expressed by a formula (Bi₂O₂)(Aₘ₋₁BₘO₃ₘ₊₁) (_{m=1, 2, 3, 4, 5}), in which A includes at least one element selected from a group consisting of Ba, Sr, Pb, Ca, K, and Bi; and B is at least one element selected from the group consisting of Nb, Ta, Ti, and W; and examples of compounds expressed by the formula (Bi₂O₂)(A_{m i}BₘO₃ₘ₊₁) (_{m=1, 2, 3, 4, 5}) include Bi₄Ti₃O₁₂, SrBi₂Ta₂O₉, SrBi₂Nb₂O₉; and another example such as Ta₂O₆ is also included.

In the descriptions as to the first to the fourth embodiments of the present invention, although materials such as Ru, Ir, or IrO₂ are referred as examples which are in contact with the high dielectric constant or ferroelectric films, any materials can be used, if a leakage characteristic as a dielectric film or the hysteresis characteristic as a ferroelectric film are satisfactorily stainable. Preferable materials include metals such as Ru, Re, Os, Ir, Rh, W, and oxides of those metals; at least one compound selected from silicides; and at least one material selected from Pt, Pd, and Rh. In particular, Ru is preferable because of its fine paterning capability, and Ir or IrO₂ are desirable because they can suppress deterioration due to the polarization fatigue.

As hereinabove described, the semiconductor memory devices of the present invention have the following effects.

The first effect of the semiconductor memory device is that it is possible to maintain the leakage current of the thin film capacitor made of the high dielectric constant film at a low level and not increasing beyond the permissible level, while the threshold voltage of the transistor is maintained at the desired value.

This effect is attained because the dangling bonds of silicon atoms at the interface between the gate insulating film and the silicon substrate are terminated by deuterium, and annealing of the high dielectric constant film is conducted which is sufficient to preserve the leakage characteristic of the high dielectric constant film at the necessary level.

The second effect of the semiconductor memory device of the present invention is that it is possible to obtain a necessary hysteresis characteristic of the thin film capacitor, while the threshold voltage of the transistor is maintained at a desired value.

This effect is attained because the dangling bonds of silicon atoms at the interface between the gate insulating film and the silicon substrate are terminated by deuterium, and annealing of the ferroelecttric film is conducted which is sufficient to preserve the hysteresis characteristic of the ferroelectric film at the preferable shape.

The third effect is that the manufacturing method of the present memory device allows the thin film capacitors made of high dielectric constant or ferroelectric films to exhibit performances as capacitors and also allows the transistors to provide long-term reliability.

This effect is attained because the dangling bonds of silicon atoms at the interface between the gate insulating film and the silicon substrate are terminated by deuterium which result in increasing the durability for the hot carriers, and an annealing of the dielectric film is conducted which is sufficient to preserve the leakage characteristic of the high dielectric constant film at the necessary level and to preserve the hysteresis characteristic of the ferroelectric film.

What is claimed is:

1. A semiconductor memory device, in which transistors and thin film capacitors formed partially or wholly by high dielectric constant or ferroelectric films are integrated on a semiconductor substrate, wherein the semiconductor memory device contains deuterium at a higher ratio than the natural abundance ratio of deuterium to hydrogen at an interface between said semiconductor substrate and a gate insulating film.

2. A semiconductor memory device, in which transistors and thin film capacitors formed by partial or whole use of high dielectric constant or ferroelectric films are integrated on a semiconductor substrate, wherein the semiconductor memory device contains deuterium at an interface between said semiconductor substrate and a gate insulating film but does not contain hydrogen.

3. A semiconductor memory device according to any one of claims 1 and 2, wherein a part or the whole of the capacitor insulating film of said thin film capacitor is formed by compounds expressed by a chemical formula ABO₃, in which A is at least one element selected from the group consisting of Ba, Sr, Pb, Ca, La, Li, and K, and B is at least one element selected from the group consisting of Zr, Ti, Ta, Nb, Mg, Mn, Fe, Zn, and W; or by compounds expressed by a chemical formula (Bi₂O₂)(A_{m 1}BₘO₃ₘ₊₁) (m=1, 2, 3, 4, 5), in which A includes at least one element selected from a group consisting of Ba, Sr, Pb, Ca, K, and Bi; and B is at least one element selected from the group consisting of Nb, Ta, Ti, and W; or by Ta₂O₅.

4. A method of manufacturing a semiconductor memory device comprising the steps of:
forming transistors;
forming thin film capacitors by use of high dielectric constant or ferroelectric film as a part or the whole of the capacitor insulating film of said thin film capacitors;
separating electrically said transistors and said thin film capacitors; and
connecting electrically said transistors and thin film capacitors;
the method further comprising the step of:
annealing in an atmosphere containing deuterium at a ratio higher than the natural abundance ratio of deuterium to hydrogen after forming the gate insulating film.

5. A method of manufacturing a semiconductor memory device comprising the steps of:
forming transistors;
forming thin film capacitors by use of high dielectric constant or ferroelectric film as a part or a whole of the capacitor insulating film of said thin film capacitors;
separating electrically said transistors and said thin film capacitors; and
connecting electrically said transistors and thin film capacitors;
the method further comprising the step of:
annealing in an atmosphere containing deuterium but not containing hydrogen after forming the gate insulating film.

6. A method of manufacturing a semiconductor memory device comprising the steps of:
forming transistors;
forming thin film capacitors by use of high dielectric constant or ferroelectric film as a part or a whole of the capacitor insulating film of said thin film capacitors;
separating electrically said transistors and said thin film capacitors; and
connecting electrically said transistors and thin film capacitors;
the method further comprising the steps of:
annealing in an atmosphere containing deuterium at a ratio higher than the natural abundance ratio of deuterium to hydrogen after forming the gate insulating film; and
annealing in an oxygen atmosphere.

7. A method of manufacturing a semiconductor memory device comprising the steps of:
forming transistors;
forming thin film capacitors by use of high dielectric constant or ferroelectric film as a part or a whole of the capacitor insulating film of said thin film capacitors;
separating electrically said transistors and said thin film capacitors; and
connecting electrically said transistors and thin film capacitors;
the method further comprising the step of:
annealing in an atmosphere containing deuterium but not containing hydrogen after forming the gate insulating film; and
annealing in an oxygen atmosphere.

8. A method of manufacturing a semiconductor memory device comprising the steps of:
forming transistors;
forming thin film capacitors by use of high dielectric constant or ferroelectric film as a part or a whole of the capacitor insulating film of said thin film capacitors;
separating electrically said transistors and said thin film capacitors; and
connecting electrically said transistors and thin film capacitors;
the method further comprising the step of:
annealing in an atmosphere containing deuterium at a ratio higher than the natural abundance ratio of deuterium to hydrogen after forming the gate insulating film; and
annealing in an atmosphere containing nitrogen or an innert gas or a mixture of nitrogen and an innert gases.

9. A method of manufacturing a semiconductor memory device comprising the steps of:
forming transistors;
forming thin film capacitors by use of high dielectric constant or ferroelectric film as a part or a whole of the capacitor insulating film of said thin film capacitors;
separating electrically said transistors and said thin film capacitors;
connecting electrically said transistors and said thin film capacitors;
the method further comprising the steps of:
annealing in an atmosphere containing deuterium but not containing hydrogen after forming the gate insulating film; and
annealing in an atmosphere containing netrogen or an innert gas or a mixture of nitrogen and an innert gases.
